(19) United States
(12) Patent Application Publication
(10) Pub. No.: US 2005/0286213 A1
(43) Pub. Date: Dec. 29, 2005

(54) Modular Control Panel Assembly

(76) Inventor: John Rooney, London (GB)

Correspondence Address: John Rooney, 68 Byne Road, London, SE26 5JD, GB

(21) Appl. No.: 11/162,281

(22) Filed: Sep. 5, 2005

(30) Foreign Application Priority Data
Mar. 5, 2004 (WO) PCT/GB04/00991
Mar. 5, 2005 (GB) 0405050.6

(51) Int. Cl. H05K 5/00

(52) U.S. Cl. 361/679

(57) ABSTRACT

The present invention relates to a modular control panel assembly, in the preferred embodiment implemented as a modular computer input device that allows a customized set-up to be created using panels and one or more housing chassis.

The present invention relates to a modular control panel assembly, in the preferred embodiment implemented as a modular human-computer input and output device that allows a customised set-up to be created using panels and one or more housing chassis.

Computers are powerful tools and they have a wide variety of uses in many fields of industry and recreation. Computers are designed by default as universal machines exemplified by their input devices, namely a pointing device and a keyboard for inputting alphanumeric characters. This is fine for the majority of computer applications and, when required, adaptations have been made dependant on its intended use, e.g. touch screens, industrial-use keyboards/trackballs and tablet+stylus.

In the audio production industry, computers are used heavily for all manner of tasks such as editing sound files, arranging songs, mixing audio tracks and playing virtual instruments. The capabilities of today's computers, together with the latest innovations in software, have made it possible to contain sufficiently a whole music studio within one computer. As computers have taken over tasks previously undertaken by dedicated external equipment, such as sequencers, samplers and effects units, the hands-on control and the mental and physical separation of different equipment has been lost. Both these aspects are important as they lend themselves heavily to human ergonomics and divided concentration respectively; both of which, when absent, lead to a significant decrease in productivity and efficiency. As a direct reaction to the evolving computer music studio, dedicated controllers for computer audio production have begun to emerge. Available at present are products usually incorporating faders, buttons, jog/shuttle wheels and LED indicators. These products are stand-alone and incompatible with each other; however, some of them can be expanded by adding extra sets of faders. These controllers communicate with the industry standard software using either common languages, such as MIDI commands and keyboard shortcuts or, through collaboration, communicate directly in a deeper level of the software. By providing controls such as faders and dedicated buttons to perform the tasks outlined above, the user returns to the more productive way of working—ergonomically and instinctively. However, the audio production industry suffers from a lack of a unified system for dedicated controllers.

The present invention seeks to provide an improved control panel assembly for a computer.

According to an aspect of the present invention, there is provided an interface assembly for interfacing to an electronic device including at least one chassis and one or more removable panels provided with control elements, said panels having predetermined dimensions substantially matched to dimensions of the at least one chassis.

The preferred embodiments provide an adaptable solution to the problems identified above and a controller that can grow and evolve in dependence upon a user's needs and on the future developments of the industry. The preferred control panel can be a standard that makers of innovative controllers and software makers alike can develop into; a foundation, upon which, the physical human-computer interaction of the future ‘computer-based’ studio can be built.

Preferably, the or at least one panel contains buttons for executing functions in multimedia software and/or faders, encoders and potentiometers for controlling variable parameters.

Embodiments of the present invention are described below, by way of example only, with reference to the accompanying drawings, in which:

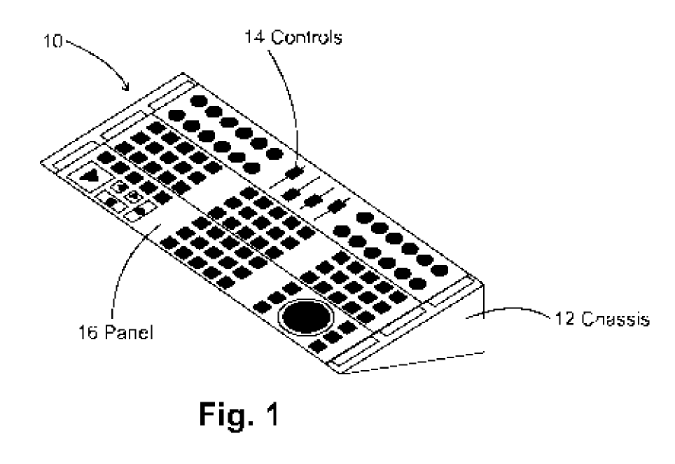

FIG. 1 is a schematic diagram of an embodiment of modular control panel assembly;

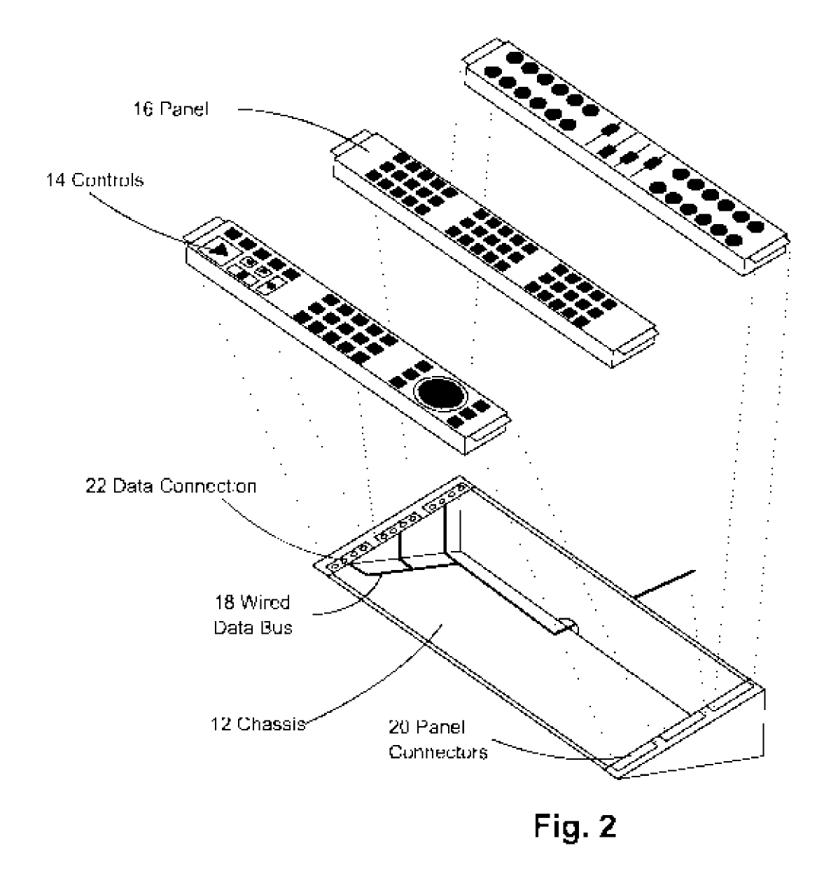

FIG. 2 is an exploded view of the control panel assembly of FIG. 1;

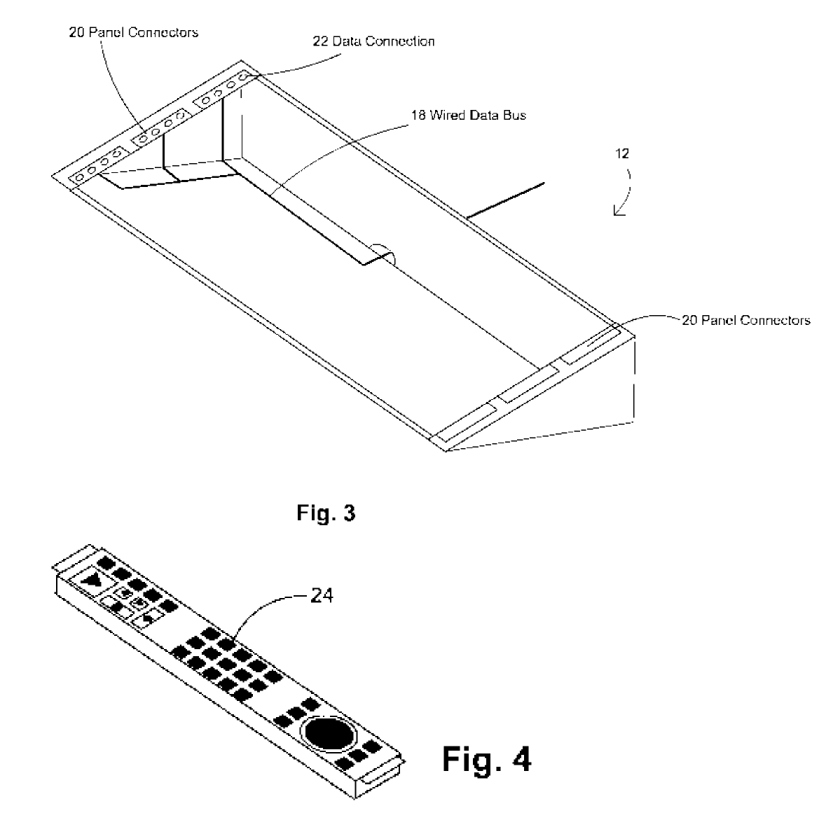

FIG. 3 is an enlarged view of a chassis member of the control panel assembly of FIGS. 1 and 2;

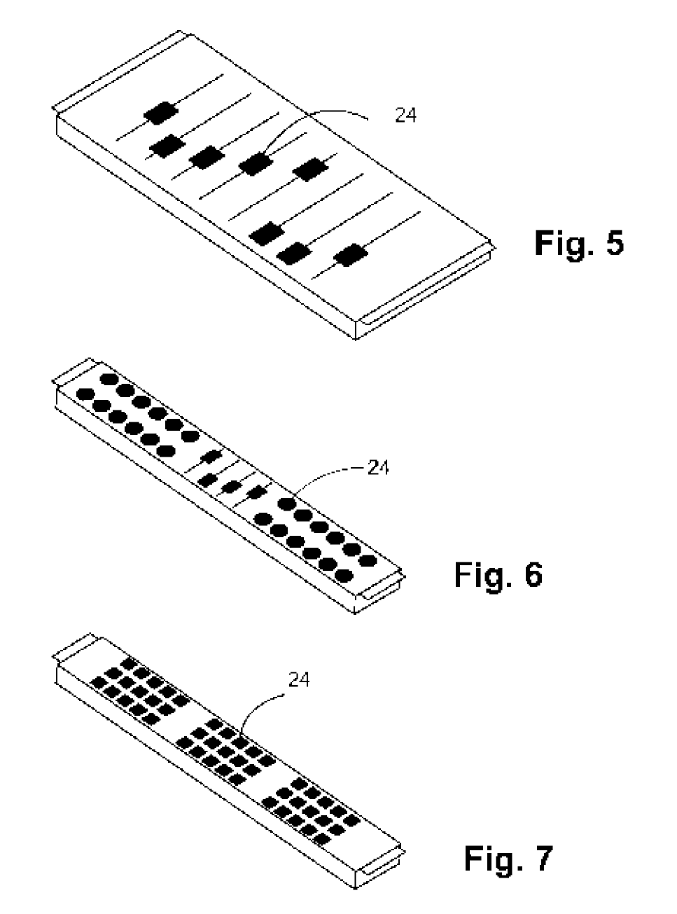

FIGS. 5 to 8 show various embodiments of control panels of the assembly of FIGS. 1 and 2;

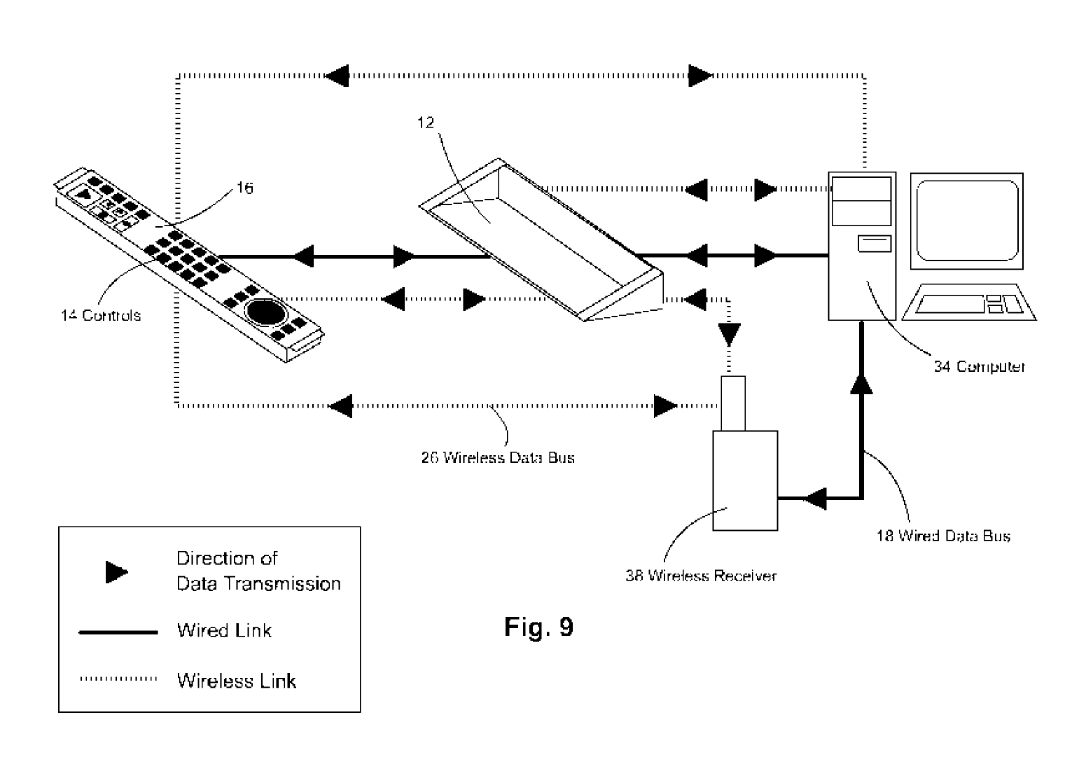

FIG. 9 shows an embodiment of the assembly of FIGS. 1 and 2 connected to a computer system; and

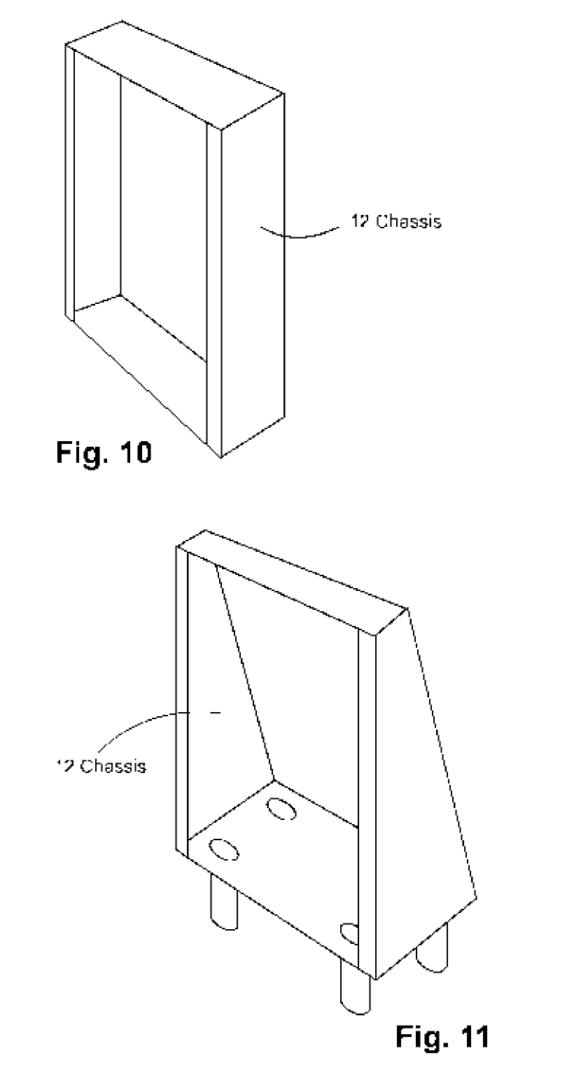

FIGS. 10 to 15 show different embodiments of chassis.

The preferred embodiment of assembly 10 is provided with a chassis member 12 and a plurality of control panels 16. The control panels 16 are preferably designed so as to be slotted into chassis 12. The panels 16 contain all the user controls 14, such as sliders, buttons, wheels and potentiometers. The chassis 12 contains the link to a computer. The panels 16 are slotted into the chassis 12, which thereby activates the panels 16 by allowing the information from the controls 14 to be transmitted to the computer.

More specifically, referring to FIG. 3, the chassis 12 provides the physical frame in which to create a customised controller assembly. The chassis 12 is designed to house the individual panels 16 by providing a standard fitting. This standard allows the chassis 12 to take on a variety of physical forms, such as desktop, floor standing and upright, as long as provision is made for the standard panel fittings.

The example of chassis shown in FIG. 3 is a desktop chassis as this is the most ergonomic, practical and common form of control panel. The desktop chassis 12 angles the installed panels 16 (as can be seen in FIG. 1) at an ergonomic angle similar to a QWERTY keyboard, thus providing comfortable access to the controls. In some embodiments, the chassis 12 allows the user to position the panels 16 as preferred within the chassis 12.

In this embodiment, the chassis 12 can be thought of as an empty frame that is connected to a data bus 18. It is open and ready to accept the fitting of panels 16.

The chassis provides three principal features. It includes panel connectors 20 which provide the physical connections for a panel 16 to fit into. They could also provide the means for a panel 16 to link to the data bus 18, such as the data connection 22. It is envisaged that standards would be provided which will allow panels 16 to be interchanged, these standards including the size of the panels and the way in which they connect to the chassis 12. The panels 16 could, for example, connect to the chassis 12 by the left and right sides; therefore a standard width size may be required. If the panel width is set, the height can also be set, however, there is the scope to design panels 16 of double or triple height should the panel design require it by designing the panel to take the space of two or more standard panels.

The physical connection between a panel 16 and the chassis 12 can also contain the data connection 22. This data connection 22 allows the controls on a panel to transmit their data via the chassis to the computer. The data connection 22 can also supply the panel 16 with power if necessary or it could be supplied on a separate connection. The panel connectors 20 preferably feature a fixing that holds the panel securely in place.

In the preferred embodiment, the data bus 18, described in further detail below, allows the information from the controllers 14 on a panel 16 to travel to the computer. The chassis 12 provides a means for this data bus 18 to exist and to continue. The chassis 12 allows the data bus 18 to extend to the connected panels 16 and to carry on through to a next chassis, if connected.

In the preferred embodiment, the assembly 10 is powered from a USB port or another connection that can derive power from the computer. However, some panels 16 may require an external power source. Panels requiring an external power source may include displays. In such an event, a direct power supply (not shown) can be installed into the chassis 12 or as an external unit that is sufficiently routed to supply power to the components that require it.

FIGS. 4 to 8 show different examples of control panels 24-32. These panels represent the user interface of the system. A panel 24-32 will normally contain both input controllers such as buttons, faders, rotary knobs, switches and joysticks, or output devices such as LEDs, LCD displays and even touch-screen displays. This is achievable as the data bus 18 can be a two-way connection. To ensure that they are compatible and interchangeable within the chassis 12, panels 24-32 will need to follow certain standards in terms of both physical size and their connection to the data bus. Variation in the size standard is the height that the panels can take. For example, if the letters NU represented the standard panel size, then a panel the size of one slot would be 1 NU in size and double and triple sized panels would be 2 NU and 3 NU respectively and multiples/fractions of the standard thereof, for example ¼ NU, ½ NU. Width could also be subject to multiples or fractions of the standard size. For example, one panel could provide a row of knobs requiring only a 1 NU slot whereas a collection of long-throw faders might require a 2 NU or even 3 NU slot, also, a Jog/Shuttle wheel could be housed in a ½ width panel 32 (FIG. 8) as long as provision is made for its secure fitting into the chassis (such as another panel of similar width or a filling dummy panel).

FIG. 4 shows an example of transport panel 24, which consists of both buttons and a Jog/Shuttle wheel. In the audio and video industry, “transport” controls refer to buttons dedicated to controlling the recording and playback of music. Play, Record, Fast Forward, Rewind and Pause are common functions covered by such controls. The transport panel 24 contains buttons for these functions as well as more advanced ones such as “Forward by Frame” and “Play from Beginning”. The Jog/Shuttle wheel allows fast and accurate navigation through a song and is a common feature in transport controllers.

FIG. 5 shows an example of mixer panel 26. Faders are used in audio production to adjust the volume of individual tracks and potentiometers are used to adjust their stereo positioning. In video editing, these controls may be used to adjust variable parameters such as fades, colour changes and effects. In the audio industry, a collection of faders and potentiometers is generally called a mixer and is the function of the mixer panel 26. The mixer panel 26 contains faders and, due to the size of the faders, it may need to be designed as a double or triple unit, that is 2 NU or 3 NU.

FIG. 6 shows an example of expression panel 28. This 1 NU panel is a collection of potentiometers, mini faders, encoders and buttons. The need for such controllers is reflected in their presence on hardware equipment such as synthesisers, samplers and effects units. They allow control over variable parameters. This was lost in the hardware to software migration as these parameters on the software emulations had to be controlled via a mouse. The expression panel 28 is a generic controller designed to work with any software including soft-synthesisers, soft-samplers and plug-in effects, generally, parameters that would benefit from variable control. The expression panel 28 could come in a variety of forms such as all-pots, all-faders or a mixture of various controllers.

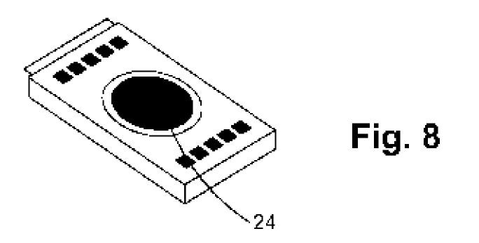

FIG. 7 shows an example of an advanced panel 30 which contains a set of programmable buttons. These buttons give the user advanced editing capabilities by providing direct access to the software functions. The user can programme each key by assigning functions to them using the configuration software.

The preferred embodiment of assembly is configured and controlled using a software programme. This configuration software recognises all connected panels and gives the user control over configuring the system. There are two preferred options as to how the panels 16 can control an application. First, using the configuration software to program the functions of the controllers on the panel and then to storing this in memory within the system or within the host computer. Alternatively or additionally, the software will act as a translator to interpret the information received from the controllers then translate it into a command that the application will recognise.

In the first instance, the panels 16 can be programmed by the software to send out commands recognised by the application and are then able to communicate directly with the application. Once the panels 16 are programmed, the software is not required to be actively running during the operation of these panels as they communicate using commands recognised by the application.

In the second instance it acts as the communication between the system and the intended application. The panels 16 send out commands that the configuration software recognises and intercepts, the software then translates this according to the user's or default configurations into commands recognised by the application. This requires the software to be active in the background in order to intercept and translate the panel's data. Either or both instances can be present in the Configuration software and applied, if preferred or necessary, to that particular panel/controller/application.

The Configuration software can also make use of patches written by the application makers specifically to enhance the communication between the control panel assembly 10 and the application.

Individual panels 16 could have their own utility within the configuration software dedicated to the specific controls present on the panel. The utility lets the user programme the functions of each controller and to assign the panels 16 to particular applications.

FIG. 9 shows an example of a data bus structure. Once a panel 16 is fitted into a connected chassis 12, it is capable of being in communication with the host computer 34 and the intended application therein. The data bus structure that runs throughout the system makes this possible; it preferably ensures that all panels 16 are in two-way communication with the computer.

USB is the preferred connection; in any case, the data bus needs to be broad enough in terms of bandwidth to allow a wide variety of controllers to communicate through the same bus or busses. Two-way communication allows programming of the assembly 10 from the computer 34. If the data bus is too narrow in terms of bandwidth, an option could be to provide for hi-speed data transfer by allowing additional cable routing within the chassis.

The data bus structure can be a wired 18 and/or a wireless 36 connection, as long as the data is transmitted from the controller on the panel 16 to the computer 34 and vice versa. There are many options as to how the panels 16 can communicate with the computer 34.

For example, when the user adjusts a controller on a connected panel 16, the data could travel as follows:
(1) data travels from the controller 14 on the panel 16 to the chassis 12;
(2) the chassis 12 houses the wired data bus 18 and connects the bus to the computer 34;
(3) the chassis 12 communicates with the host computer 34.
   Alternatively,
(1) the data from the controller 14 transmits wirelessly (e.g. via Bluetooth/wi-fi) to a receiver 38;
(2) the receiver 38 transfers the data to the computer 34. Of course, communication could also be as follows:
(1) the data transmits wirelessly direct to a receiver built into the computer 34 e.g. a motherboard with built-in Bluetooth/wi-fi.

The data bus (es) 18, 36 preferably allows two-way communication, as the configuration software and/or the intended application may also need to communicate with the panels 24-32 or the chassis 12. This may be required to send information to controllers or displays on the panels such as configuration information or controller information such as fader positions, LED status, display screens.

The assembly 10 and the computer may in some embodiments communicate via a central hub. The function of such a hub is essentially to provide a central base for the system. It will connect to a chassis that will in turn communicate with any other chassis and panels via the data bus 18, 36. The hub could also allow a multiple of chassis to connect to it. The central hub could provide a power source to the connected panels 16 and could contain memory for certain panel configurations. The hub is preferably expandable to provide certain options to the user; these could include a Bluetooth add-on for wire-free controllers and a memory upgrade if necessary. In this case, the hub would act as the receiver for the wireless data bus 36 mentioned above. The hub will connect and communicate with the host computer 34.

The concept of the assembly described above is one that can be applied to many industries such as audio production, video editing, graphic design, point-of-sale, medical, broadcast, lighting, CAD, military, and security. Basically, it would benefit any industry or field that requires a greater amount of ergonomic control over computer software. Now follows an example of assembly in an audio production studio, from a sound engineer's point of view.

The sound engineer in a professional audio production studio follows the progress of the industry and its latest developments. The following equipment may be used in such a studio: recording and arranging: 1 PC, 1 software sequencer; audio signal mixing: 32-track mixer. Electronic instruments may include: 1 synthesiser, 2 samplers, a MIDI keyboard. Digital signal processing/effects units may include: 1 reverberator, 1 multi-effects unit, 1 delay, 4 equalisers, 4 compressors.

The sound engineer first connects a desktop chassis 12 with two 1 NU panels 18 to his computer, the transport panel 24 and one advanced panel 30, to give him better control over certain functions of the software sequencer. If he later found that he used the software sequencer for mixing the audio files in the computer rather than routing them out to the 32-track mixer, he would replace his 32-track mixer with a mixer panel 26 to control his sequencer. So, he could connect four desktop chassis 12 together and fit a 3 NU mixer panel in each to give him 32 faders to control the software sequencer. Having evaluated a software-sampler, he would have found its capabilities and quality were on a par with his hardware sampler and with the added benefit of upgradeability and better communication with his software sequencer. Previously, he would have found he had lost the hands-on control of the equipment he previously had with the external equipment and had to resort to the computer mouse. However, he overcomes this by installing an expression panel 28 to control the variable parameters within the software-sampler.

The modular system allows for the incorporation of new panels 18 as and when they become available from a supplier.

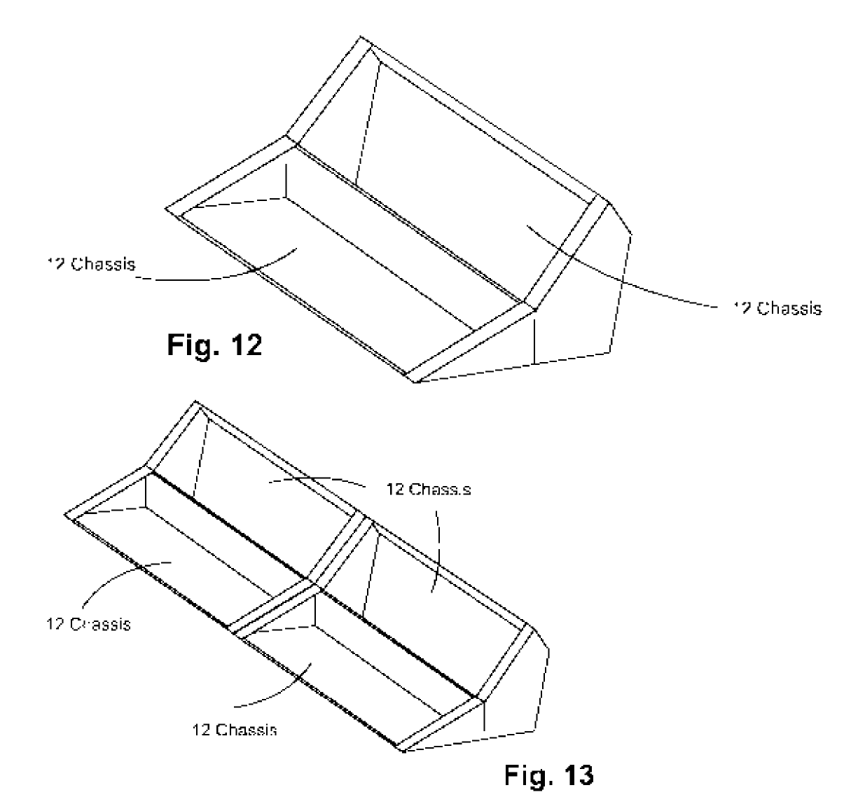

Referring to FIGS. 10 to 12, the chassis can take on a variety of forms as long as they adhere to standard specifications for panel fittings outlined above. Besides the desktop type of FIG. 3, the chassis can take on physical variations such as upright (FIG. 10), floor-standing (FIG. 11) or double desktop (FIG. 12). The purpose of these variations is to position the panels in ergonomic and easy-to-reach places.

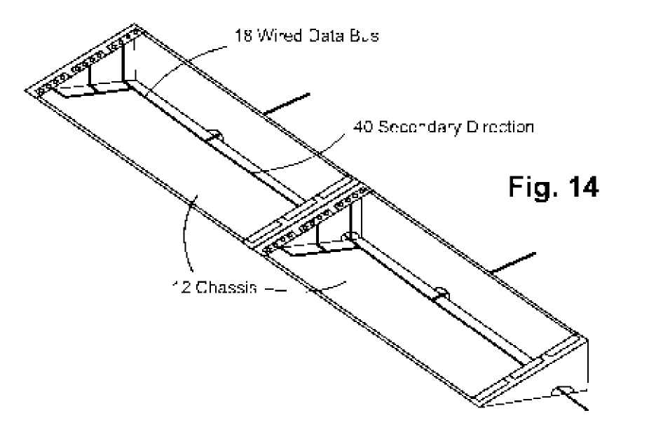

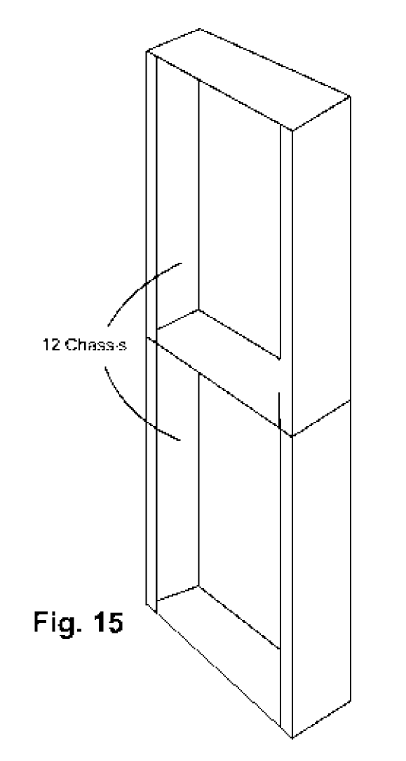

FIGS. 13 to 15 show various examples of inter-connectable chassis. As this can be an expandable system, connecting chassis together can increase the amount of available panel spaces. For this, the chassis concerned are provided with inter-connectors to ensure a flush and secure joining. These inter-connectors can be built into the chassis or can be an optional add-on device that achieves this same function. FIG. 13 shows two connected chassis including attached double desktops (see FIG. 12). FIG. 14 shows two connected desktop chassis (FIG. 3) and FIG. 15 shows connected upright chassis (FIG. 10).

If the data bus is a wired connection, then a link is preferably established between the connected chassis. This can provide a secondary direction 40 for the data bus 18 to travel, branching off from the primary bus to form a connection to another chassis as shown in FIG. 14.

As mentioned above, the assembly can be used in many industries and applications. This is due to the modular nature of the system. The described embodiments are directed to the creative industry. However, they can be modified for other industries, such as military, medical and architectural planning. For example, medical equipment is fast becoming computer based, however, nurses and doctors would benefit from dedicated controls such as those found on individual medical equipment rather than the usual keyboard and mouse. Where software can complete the same tasks as those of dedicated equipment, control over this software could be provided by familiar controls such as buttons, potentiometers, encoders and displays all being built into dedicated panels 16 and housed in the chassis 12.

1. An interface assembly for interfacing to an electronic device including at least one chassis and one or more removable panels provided with control elements, said panels having predetermined dimensions substantially matched to dimensions of the at least one chassis.

2. An assembly according to claim 1, including a plurality of chassis designed to be releasably, mechanically and/or electrically connectable to one another.

3. An assembly according to claim 1 or 2, including a plurality of panels designed to be releasably, mechanically and/or electrically connectable to the or at least one chassis.

4. An assembly according to any preceding claim, wherein the or each chassis is provided with an aperture designed to accept one or more panels.

5. An assembly according to any preceding claim, wherein the controls of the panels are designed to communicate with a computer directly, via the chassis or via a central hub.

6. An assembly according to any preceding claim, wherein the or at least one panel is provided with buttons for controlling transport functions of software.

7. An assembly according to any preceding claim, wherein the or at least one panel is provided with one or more motorised or non-motorised faders, one or more potentiometers, encoders and/or a jog wheel and/or a shuttle wheel for controlling variable parameters in software.

8. An assembly according to any preceding claim, wherein the or at least one panel contains buttons for executing functions in software and/or joysticks for controlling variable parameters in software.

9. An assembly according to any preceding claim, wherein the or at least one panel is provided with a T-bar.

10. An assembly according to any preceding claim, wherein the or at least one panel is provided with a computer display and/or a touch-sensitive computer display and/or light emitting diodes and/or one or more liquid crystal displays and/or a touch-sensitive controller.

11. An assembly according to claim 10, wherein the display, diode or controller is controllable by a host computer.

12. An assembly according to any preceding claim, wherein the or at least one panel is provided with one or more electronic input devices or output devices designed for human-computer interaction and/or computer-computer interaction.

13. An assembly according to any preceding claim, wherein the or at least one chassis is provided with one or more electronic input devices or output devices designed for human-computer interaction and/or computer-computer interaction.

14. An assembly according to any preceding claim, including a data bus in communication with a computer and the at least one panel.

15. An assembly according to claim 14, wherein the data bus is able to be connected to a second chassis.

16. An assembly according to claim 15 or 15, wherein the data bus is a wired data bus and/or a wireless data bus.

17. An assembly according to any preceding claim, including fittings allowing one or more chassis to be securely connected together.

18. An assembly according to claim 17, wherein the fittings are removable.

19. An assembly according to any preceding claim, including a central hub through which communications are made to pass.

20. An assembly according to claim 19, wherein the central hub is operable to provide power to the or at least one panel and/or the chassis.

21. An assembly according to any preceding claim, including software and/or firmware designed to translate, substantially in real time, data received from the or at least one panel into Musical Instrument Digital Interface (MIDI) commands, into keyboard shortcuts (ASCII commands), or into a language/protocol recognised by software installed on the receiving computer or other electronic device.
